(19) United States
(12) Patent Application Publication
(10) Pub. No.: US 2006/0183028 A1
(43) Pub. Date: Aug. 17, 2006

(54) Method for producing a mask layout avoiding imaging errors for a mask

(76) Inventors: Christian Meyne, Muenchen (DE); Eva Nash, Adelshofen (DE); Armin Semmler, Muenchen (DE)

Correspondence Address: SLATER & MATSIL LLP, 17950 PRESTON ROAD, SUITE 1000, DALLAS, TX, 75252, US

(21) Appl. No.: 11/332,829

(22) Filed: Jan. 13, 2006

(30) Foreign Application Priority Data
Jan. 14, 2005 (DE) 10 2005 002 529.3

(51) Int. Cl. G03C 5/00; G03F 1/00

(52) U.S. Cl. 430/5; 430/311; 430/312; 430/313

(57) ABSTRACT

In a method for producing a final mask layout for a mask, a provisional auxiliary mask layout is generated in accordance with an electrical circuit diagram. The provisional mask layout includes a main structure that extends in a longitudinal direction. The provisional auxiliary mask layout is converted into a final mask layout with the aid of an OPC method. The converting includes associating at least one optically non-resolvable auxiliary structure with the main structure, wherein the at least one optically non-resolvable auxiliary structure has a longitudinal direction that extends obliquely with respect to the longitudinal direction of the main structure.

This application claims priority to German Patent Application 10 2005 002 529.3, which was filed Jan. 14, 2005, and is incorporated herein by reference.

### TECHNICAL FIELD

The invention relates to a method for producing a final mask layout and using the layout to fabricate a semiconductor device.

### BACKGROUND

It is known that, in lithography methods, imaging errors can occur if the structures to be imaged become very small and have a critical size or a critical distance with respect to one another. The critical size is generally referred to as the “CD” value (CD: critical dimension).

What is more, imaging errors may occur if structures are arranged so closely next to one another that they mutually influence one another during the imaging. These imaging errors, based on “proximity effects,” can be reduced by modifying the mask layout beforehand with regard to the “proximity phenomena” that occur. Methods for modifying the mask layout with regard to avoiding proximity effects are referred to by experts by the term OPC methods (OPC: optical proximity correction).

FIG. 1 illustrates a lithography process without OPC correction. The illustration reveals a mask 10 with a mask layout 20 that is intended to produce a desired photoresist structure 25 on a wafer 30. The mask layout 20 and the desired photoresist structure 25 are identical in the example in accordance with FIG. 1. A light beam 40 passes through the mask 10 and also a focusing lens 50 arranged downstream and falls onto the wafer 30, thereby imaging the mask layout 20 on the wafer 30 coated with photoresist. On account of proximity effects, imaging errors occur in the region of closely adjacent mask structures with the consequence that the resulting photoresist structure 60 on the wafer 30 in part deviates considerably from the mask layout 20 and thus from the desired photoresist structure 25. The photoresist structure that results on the wafer 30, the photoresist structure being designated by reference number 60, is illustrated in enlarged fashion and schematically beneath the wafer 30 for improved illustration in FIGS. 1 and 2.

In order to avoid or to reduce these imaging errors, it is known to use OPC methods that modify the mask layout 20 beforehand in such a way that the resulting photoresist structure 60 on the wafer 30 corresponds to the greatest possible extent to the desired photoresist structure 25.

FIG. 2 shows a previously known OPC method described in the document “A little light magic” (Frank Schellenberg, IEEE Spectrum, September 2003, pages 34 to 39), which is incorporated herein by reference, in which the mask layout 20′ is altered compared with the original mask layout 20 in accordance with FIG. 1. The modified mask layout 20′ has structure alterations that are smaller than the optical resolution limit and, therefore, cannot be imaged “1:1”. These structure alterations nevertheless influence the imaging behavior of the mask, as can be discerned at the bottom of FIG. 2; this is because the resulting photoresist structure 60 corresponds distinctly better to the desired photoresist structure 25 than is the case with the mask in accordance with FIG. 1.

In the case of the previously known OPC methods by which a “final” mask layout (see mask 20′ in accordance with FIG. 2) is formed from a provisional auxiliary mask layout (e.g., the mask layout 20 in accordance with FIG. 1), a distinction is made between so-called “rule-based” and “model-based” OPC methods.

In the case of rule-based OPC methods, the formation of the final mask layout is carried out using rules, in particular tables, defined beforehand. The method disclosed in U.S. Pat. Nos. 5,821,014 and 5,242,770, both of which are incorporated herein by reference, by way of example, may be interpreted as a rule-based OPC method, in the case of which optically non-resolvable auxiliary structures are added to the mask layout according to predetermined fixed rules, in order to achieve a better adaptation of the resulting photoresist structure (reference number 60 in accordance with FIGS. 1 and 2) to the desired photoresist structure (reference number 25 in accordance with FIGS. 1 and 2). In the case of these methods, then, a mask optimization is carried out according to fixed rules.

In model-based OPC methods, a lithography simulation method is carried out, in the course of which the exposure operation is simulated. The simulated resulting photoresist structure is compared with the desired photoresist structure, and the mask layout is varied or modified iteratively until a “final” mask layout is present, which achieves an optimum correspondence between the simulated photoresist structure and the desired photoresist structure. The lithography simulation is carried out with the aid of, for example, a DP-based lithography simulator that is based on a simulation model for the lithography process. For this purpose, the simulation model is determined beforehand by “fitting” or adapting model parameters to experimental data. The model parameters may be determined for example by evaluation of so-called OPC curves for various CD values or structure types. One example of an OPC curve is shown in FIG. 2A and will be explained in connection with the associated description of the figures. Model-based OPC simulators or OPC simulation programs are commercially available. A description is given of model-based OPC methods for example in the article “Simulation-based proximity correction in high-volume DRAM production” (Werner Fischer, Ines Anke, Giorgio Schweeger, Jörg Thiele; Optical Microlithography VIII, Christopher J. Progler, Editor, Proceedings of SPIE VOL. 4000 (2000), pages 1002 to 1009) and in German Patent No. DE 101 33 127 C2, both of which are incorporated herein by reference.

Irrespective of whether an OPC method is a model-based or a rule-based OPC method, OPC variants can also differ with regard to their respective optimization aim. By way of example, so-called “target” OPC methods and so-called process window OPC methods, for example “defocus” OPC methods, have different optimization aims.

The aim of target OPC methods is to hit as accurately as possible the predefined target for the individual geometrical dimensions of the mask structures in the case of correctly complying with all the predefined technological and method conditions (e.g., focus, exposure dose, etc.). Thus, in the case of a target OPC variant it is assumed that all the predefined process parameters are “hit” or set and complied with in an ideal way. In this case, the term “target” is understood to mean the structure size of the main structures to be imaged.

Since the gate length of transistors is of crucial importance for their electrical behavior, target OPC methods are used in particular for the gate plane of masks. What is disadvantageous in the case of the target OPC variant, however, is that the predefined geometrical dimensions of the mask structures are actually complied with only when the predefined process parameters are hit in a quasi exact fashion. If fluctuations in the process parameters occur, it is possible for, in some instances, considerable deviations to occur between the desired mask structures or mask dimensions and the actual resulting mask structures or mask dimensions. This may lead, for example, to a tearing away of lines or to a short circuit between lines. The resulting process window is, therefore, generally relatively small in the case of a target OPC method.

By contrast, process window OPC methods, for example defocus OPC methods, have the aim of making the process window—that is to say the permissible parameter range of the process parameters for the exposure process with the resulting mask—as large as possible in order to ensure that the mask specifications are complied with even in the case of process fluctuations. In this case, with defocus OPC methods it is accepted that the geometrical mask target dimension is not hit exactly. Deviations are, therefore, deliberately accepted in order to enlarge the process window and thus the tolerance range during later use of the mask.

A defocus OPC method is described for example in the above-mentioned German Patent No. DE 101 33 127. This method involves predefining a “fictitious” defocus value, which is taken as a basis for the simulation of the exposure operation. This defocus value specifies that the resist structure to be exposed with the mask lies somewhat outside the optimum focal plane. In the context of the OPC method, an attempt is made to achieve an optimum imaging behavior of the mask despite the defocusing purportedly present. Thus, an attempt is made to compensate for the imaging error caused by the purported defocusing. This “compensation operation” has the effect of changing the form of the mask layout in such a way that the line structures are made wider and, as well, a larger distance is produced between two adjacent line structures in each case. As a result, a mask is thus obtained with which, when using a focused exposure, the probability of the formation of wider line structures and the formation of larger distances between respectively adjacent line structures is greater than the probability of the formation of excessively small line structures and the formation of excessively small distances between adjacent line structures.

A method for producing a final mask layout is disclosed in the publication document for the international patent application WO 03/021353. In the case of this method, for the purpose of producing a final mask layout, avoiding imaging errors, for a mask, a provisional auxiliary mask layout produced—in particular in accordance with a predefined electrical circuit diagram—is converted into the final mask layout with the aid of an OPC method. In the case of the previously known method, a main structure of the provisional auxiliary mask layout is assigned optically non-resolvable auxiliary structures, which are arranged perpendicular to the main structure.

What is problematic is that the optically non-resolvable auxiliary structures cannot always be positioned ideally. By way of example, the distance between the main structures may be too small to be able to arrange perpendicular auxiliary structures between the main structures. This results in layout regions that do not enable any optimization with optically non-resolvable auxiliary structures. Such layout regions are accordingly “forbidden” to prevent imaging errors of the mask. The “permitted” layout region is thus delimited by the “forbidden” layout region.

### SUMMARY OF THE INVENTION

In one aspect, the invention specifies a method that provides a larger “permitted” layout region than the previously known method explained.

In the case of a method of the type specified in the introduction, the method is provided for producing a final mask layout for a mask. The method generates a provisional auxiliary mask layout in accordance with a predefined electrical circuit diagram, which includes a main structure that extends in a longitudinal direction. The provisional auxiliary mask layout is converted into a final mask layout with the aid of an OPC method, wherein the converting includes associating at least one optically non-resolvable auxiliary structure with the main structure, wherein the at least one optically non-resolvable auxiliary structure has a longitudinal direction that extends obliquely with respect to the longitudinal direction of the main structure.

Accordingly, it is provided according to embodiments of the invention that the at least one optically non-resolvable auxiliary structure is arranged obliquely with respect to the main structure.

One advantage of the method according to embodiments of the invention can be seen in the fact that it can be used to provide auxiliary structures even for layout regions that cannot be provided with such structures using the previously known methods because the distance between adjacent main structures is too small for this. Specifically, when there is an excessively small distance between the main structures, perpendicular auxiliary structures cannot be accommodated in terms of space between the main structures because it is dictated technically that certain minimum lengths have to be complied with for auxiliary structures in order that they can be “written” into the masks reproducibly with the aid of the mask writing apparatuses available at the present time. If the distance between the main structures falls below this technically dictated minimum length, then it is no longer possible to use perpendicular auxiliary structures. Sometimes a use of parallel auxiliary structures is also not practical in such a case because the distance between the main structures is in turn still too large for a layout correction with parallel auxiliary structures to be effective. It is at this point that the invention commences by virtue of embodiments of the invention providing for the auxiliary structures to be oriented obliquely with respect to the respectively assigned main structure. This makes it possible to insert auxiliary structures between adjacent main structures that are at a distance from one another that is too small for perpendicular auxiliary structures: by way of example, the distance between the main structures may be smaller by √2-fold, if the auxiliary structure runs at an angle of 45 degrees with respect to the main structure, then it is possible in the case of a perpendicular arrangement of the auxiliary structure. This will be clarified on the basis of a numerical example: if the resolution or lithography dictates that the minimum length of an auxiliary structure is 100 nm, for example, then the distance between the main structures should at most likewise be 100 nm if, for the sake of simplicity, certain necessary minimum distances between main and auxiliary structures are disregarded. If, by contrast, the auxiliary structure is arranged at an angle of 45 degrees, then the minimum distance between the main structures only has to be approximately 70 nm. The “permitted” layout region or the permitted layout window is thus considerably enlarged.

An oblique arrangement of the optically non-resolvable auxiliary structure is present for example if the longitudinal direction of the auxiliary structure extends obliquely with respect to the longitudinal direction of the assigned main structure.

The at least one optically non-resolvable auxiliary structure is preferably arranged at an angle of between 10 and 80 degrees relative to the longitudinal direction of the assigned main structure.

In this case, the enlargement of the permitted layout region or of the permitted layout window becomes all the larger, the “more obliquely” the auxiliary structure is situated relative to the assigned main structure. Accordingly, angular ranges of between 20 and 40 degrees, between 40 and 60 degrees and between 60 and 80 degrees are regarded as advantageous. An enlargement of the permitted layout window by a factor of √2 is achieved at an angle of approximately 45 degrees.

The end edges of the optically non-resolvable auxiliary structure may be configured arbitrarily. By way of example, the end edges may run perpendicular to the longitudinal direction of the auxiliary structure. However, other configurations of the end edges are also possible. It is regarded as advantageous, for example, if the end edges run parallel to the longitudinal direction of the respectively assigned main structure because a larger distance between main structure and auxiliary structure results in such a case. The larger distance is advantageous in particular for accurate mask production and reliable mask inspection. This is because masks are usually inspected and, if appropriate, repaired by means of an optical method after production. In this case, a specific minimum distance between structures must not be undershot since otherwise writing errors can no longer be reliably detected. However, a mask without sufficiently reliable inspection could not be used productively, or at the very least could only be used productively to a restricted extent.

As an alternative, the end edges may also in each case be formed by two end terminating edges which taper toward one another to a point in the longitudinal direction of the auxiliary structure. In such a case, it is regarded as particularly advantageous if, in each case, one of the two end terminating edges of the end edge runs parallel to the longitudinal direction of the respectively assigned main structure.

Moreover, the optically non-resolvable auxiliary structures may also be arranged in groups and form “obliquely running groups”, for example zebra-like structures.

As already mentioned, the optically non-resolvable auxiliary structures are arranged, for example, between two adjacent main structures. In such a case, the width of the auxiliary structures and also the distance between the auxiliary structures are preferably chosen in a manner dependent on the distance between the two adjacent main structures and/or in a manner dependent on the structure width of the two main structures.

The width of the optically non-resolvable auxiliary structures is preferably adapted to the grid point spacing of the layout structure of the mask layout. The optically non-resolvable auxiliary structures are preferably positioned with the aid of a simulation program.

By way of example, a model-based OPC method or a rule-based OPC method may be used as the OPC method. In this regard, reference is made to the above explanations in the introduction.

### BRIEF DESCRIPTION OF THE DRAWINGS

The invention is explained below on the basis of exemplary embodiments. In this case,

FIG. 1 shows an illustration of a lithographic process without OPC correction;

FIG. 2 shows an illustration of a lithographic process with OPC correction according to the prior art;

FIG. 2A shows an illustration of the dependence of the CD value on the distance between the mask structures among one another (“OPC curve”);

FIG. 3 shows two main structures to which an optically non-resolvable auxiliary structure running parallel is assigned according to a method according to the prior art;

FIG. 4 shows two main structures to which optically non-resolvable auxiliary structures running perpendicular are assigned according to a method according to the prior art;

FIG. 5 shows two main structures to which obliquely running, optically non-resolvable auxiliary structures are assigned according to a first exemplary embodiment of the method according to the invention;

FIG. 6 shows two main structures to which obliquely running auxiliary structures are assigned according to a second exemplary embodiment of the method according to the invention; and

FIG. 7 shows two main structures to which obliquely running auxiliary structures are assigned according to a third exemplary embodiment of the method according to the invention.

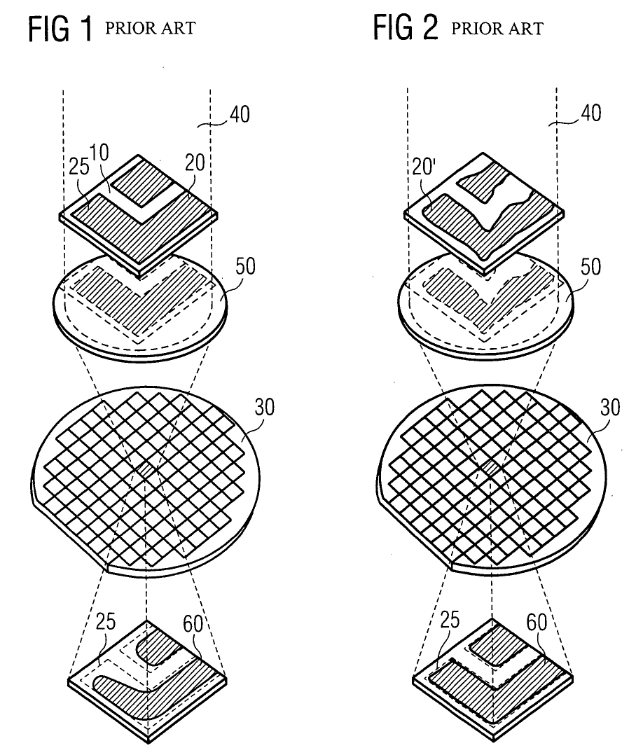

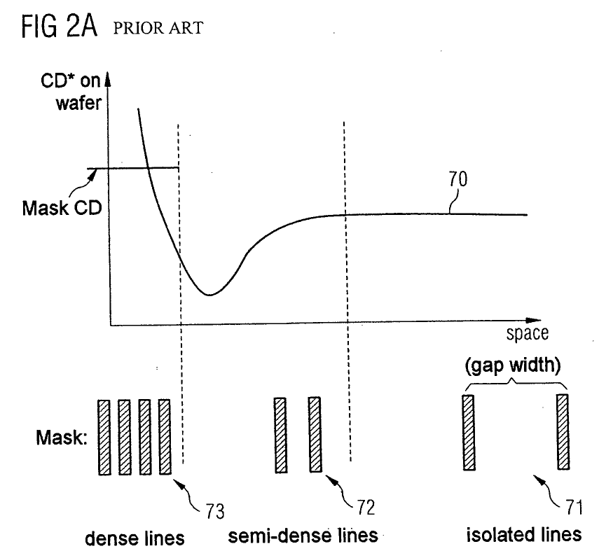

The following list of reference symbols can be used in conjunction with the figures:

| | |
|---|---|
| 10 | Mask |
| 20 | Mask layout |
| 20′ | Modified or final mask layout |
| 25 | Photoresist structure |
| 30 | Wafer |
| 40 | Light beam |
| 50 | Focusing lens |
| 60 | Resulting photoresist structure |
| 70 | OPC curve |
| 71 | Isolated lines |
| 72 | Semi-dense structures |
| 73 | Very dense structures |
| 100 | Main structure |
| 110 | Main structure |
| 120 | Longitudinal direction |
| 130 | Longitudinal direction |
| 140 | Scatterbar, non-imaging |
| 150 | Longitudinal direction |
| 200 | End edge |
| 210 | Terminating edge |
| 220 | Terminating edge |
| S | Point |
| E | Corner point |
| A | Difference between the main structures |
| Amin | Minimum distance between the main |
| | structures |
| L | Length of the scatterbars |
| Lmin | Minimum length of the scatterbars |
| d | Distance between scatterbar/main structure |
| dmin | Minimum distance between scatterbar/main |
| | structure |
| α | Angle between longitudinal direction of |
| | scatterbar/main structure |

### DETAILED DESCRIPTION OF ILLUSTRATIVE EMBODIMENTS

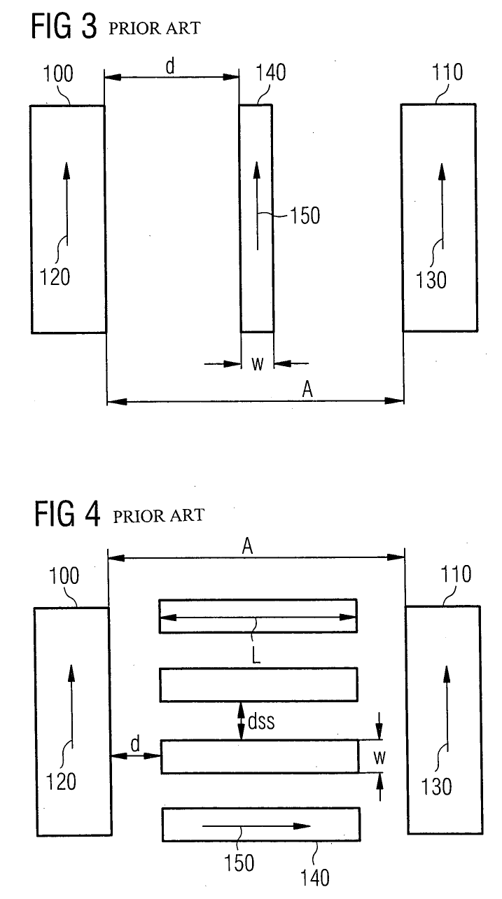

FIG. 3 reveals two main structures 100 and 110, both of which are configured in rectangular fashion. The two longitudinal directions 120 and 130 of the two main structures 100 and 110 run parallel.

Arranged between the two main structures 100 and 110 is an optically non-resolvable auxiliary structure 140 (e.g., scatterbar) formed in bar-shaped or rectangular fashion. The longitudinal direction 150 of the auxiliary structure 140 runs parallel to the two longitudinal directions 120 and 130 of the two main structures 100 and 110. In this case, the auxiliary structure 140 is arranged centrally between the two main structures 100 and 110.

The arrangement of the auxiliary structure 140 between the two main structures 100 and 110 as illustrated in FIG. 3 is effected—as already mentioned—in previously known methods according to the prior art. What is disadvantageous about this “parallel” arrangement of the auxiliary structure 140 is that when there is a very large distance A between the two main structures 100 and 110, the effect of the auxiliary structure 140 becomes very small.

In order to achieve an optimum imaging even when there are large distances A between the two main structures 100 and 110, a perpendicular arrangement of auxiliary structures 140 is provided according to another previously known method according to the prior art. This is illustrated in FIG. 4. A total of four auxiliary structures 140 can be seen, the longitudinal direction 150 of which in each case extends perpendicular to the longitudinal direction 120 of the main structure 100 and to the longitudinal direction 130 of the main structure 110. This “perpendicular” arrangement of the auxiliary structures 140 enables imaging errors to be reduced even in the case of large distances A.

What is problematic about the previously known method in accordance with FIG. 4, however, is that the length of the bar-shaped auxiliary structures 140 is not permitted to fall below a lithography-dictated or technologically dictated minimum length L. Moreover, it is necessary to comply with a minimum distance dss between the auxiliary structures 140 among one another and also a minimum distance d to the respectively adjacent main structure 100 and 110. Accordingly, “perpendicular” auxiliary structures 140 can be used only when the distance A between the two main structures 100 and 110 exceeds a predetermined minimum distance.

A first exemplary embodiment of the method according to the invention will now be explained with reference to FIG. 5. Two main structures 100 and 110 can be seen, the main structures being assigned auxiliary structures 140 (e.g., scatterbars). In contrast to the methods in accordance with FIGS. 3 and 4, the longitudinal direction 150 of the auxiliary structures 140 extends at a predetermined angle α with respect to the longitudinal direction 120 and 130 of the main structures 100 and 110, respectively, in the case of the method in accordance with FIG. 5. The auxiliary structures 140 thus run obliquely relative to the main structures 100 and 110. The angular range of the angle a preferably lies between 10 and 80 degrees. A particularly favorable value is an angle of approximately 45 degrees.

By virtue of the oblique arrangement of the auxiliary structures 140, it is possible to choose the distance A between the main structures 100 and 110 to be smaller than is possible in the case of the method in accordance with FIG. 4. This is because the length L no longer determines the minimum distance A between the two main structures 100 and 110. The smaller the angle α becomes, the closer the two main structures 100 and 110 can move to one another without the minimum length L of the auxiliary structure 140 constituting a limitation. In this case, a technological limit is merely defined by the minimum distance d from the respectively adjacent main structure 100 and 110.

It is evident in FIG. 5 that the end edges 200 of the auxiliary structures 140 run perpendicular to the longitudinal direction 150 of the auxiliary structures. The distance d between the auxiliary structures 140 and the main structures 100 and 110 is thus defined by the corner points E of the auxiliary structures 140.

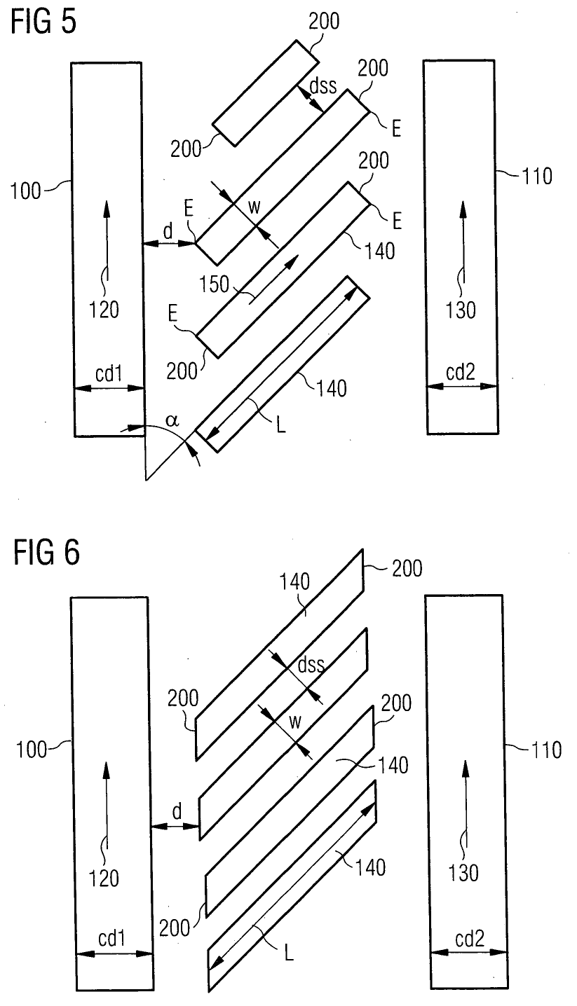

A second exemplary embodiment of the method according to the invention will now be explained with reference to FIG. 6. In contrast to the exemplary embodiment in accordance with FIG. 5, the end edges 200 of the auxiliary structures 140 run parallel to the longitudinal direction 120 and 130 of the respectively assigned main structure 100 and 110 in the case of this exemplary embodiment. Consequently, the auxiliary structures 140 form parallelograms rather than rectangles.

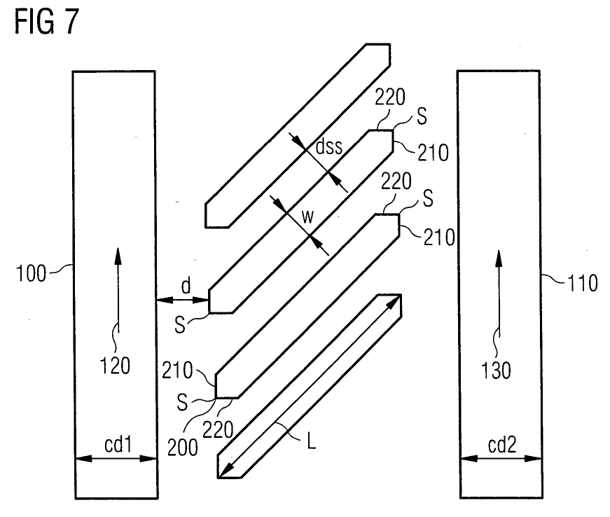

FIG. 7 shows a third exemplary embodiment of the method according to the invention. In the case of this third exemplary embodiment, the end edges 200 of the auxiliary structures 140 taper together to a point. In this case, two end terminating edges 210 and 220 respectively form a point S. In this case, one of the two end terminating edges—this is for example the edge 210—runs parallel to the longitudinal direction 120 and 130 of the adjacent main structure 100 and 110, respectively.

Regarding the width w of the auxiliary structures 140, the distance dss between the auxiliary structures 140 among one another and also the distance d between the auxiliary structures 140 and the respectively adjacent main structure 100 and 110, the following should be taken into account: the distance d is in each case to be chosen as small as possible in order that the process-window-enlarging influence of the auxiliary structures 140 is as large as possible. However, the distances d must not be too small either, since an imaging of the auxiliary structures 140 during the lithography method must always be avoided. Experience shows that the lower limit dmin for the distance d is dependent on the width w of the auxiliary structure 140 and also on the width cd1 and cd2 of the adjacent main structures 100 and 110, respectively. The smaller the width w of the auxiliary structures 140 and also the width cd1 and cd2 of the two main structures 100 and 110, respectively, the smaller the minimum distance dmin can usually be chosen. In this case, the minimum distance dmin is dependent both on the exposure process and on the mask fabrication process and generally cannot fall below a specific value for a predetermined technology. The same correspondingly holds true for the length L of the auxiliary structures 140: the length L thereof likewise usually cannot fall below a lower limit Lmin depending on the respective mask fabrication process; experience shows that the lower limit Lmin is a multiple of the minimum distance dmin and the minimum width w of the auxiliary structures 140.

In the case of an oblique arrangement of the auxiliary structures 140, the minimum distance Amin between the two main structures 100 and 110 results in accordance with the following mathematical relationship:
Amin=2*dmin+Lmin*cos α

Consequently, the smaller the angle α becomes, the more densely the two main structures 100 and 110 can move toward one another. At an angle of α=45 degrees, this therefore results in a minimum distance Amin of:
Amin=2*dmin+Lmin/√2

What is claimed is:

1. A method for producing a final mask layout for a mask, the method comprising:
generating a provisional auxiliary mask layout in accordance with an electrical circuit diagram, the provisional mask layout including a main structure that extends in a longitudinal direction; and
converting the provisional auxiliary mask layout into a final mask layout with the aid of an OPC method, wherein the converting includes associating at least one optically non-resolvable auxiliary structure with the main structure, wherein said at least one optically non-resolvable auxiliary structure has a longitudinal direction that extends obliquely with respect to the longitudinal direction of the main structure.

2. The method as claimed in claim 1, wherein the at least one optically non-resolvable auxiliary structure is arranged in such a way that the longitudinal direction of the auxiliary structure and the longitudinal direction of the associated main structure are at an angle of between 10 and 80 degrees with respect to one another.

3. The method as claimed in claim 2, wherein the at least one optically non-resolvable auxiliary structure is arranged in such a way that the longitudinal direction of the auxiliary structure and the longitudinal direction of the associated main structure are at an angle of between 20 and 40 degrees with respect to one another.

4. The method as claimed in claim 2, wherein the at least one optically non-resolvable auxiliary structure is arranged in such a way that the longitudinal direction of the auxiliary structure and the longitudinal direction of the associated main structure are at an angle of between 40 and 60 degrees with respect to one another.

5. The method as claimed in claim 2, wherein the at least one optically non-resolvable auxiliary structure is arranged in such a way that the longitudinal direction of the auxiliary structure and the longitudinal direction of the associated main structure are at an angle of between 60 and 80 degrees with respect to one another.

6. The method as claimed in claim 2, wherein the at least one optically non-resolvable auxiliary structure is arranged in such a way that the longitudinal direction of the auxiliary structure and the longitudinal direction of the associated main structure are at an angle of about 45 degrees with respect to one another.

7. The method as claimed in claim 1, wherein at least one end edge of the at least one optically non-resolvable auxiliary structure runs perpendicular to the longitudinal direction of the auxiliary structure.

8. The method as claimed in claim 1, wherein at least one end edge of the at least one optically non-resolvable auxiliary structure runs parallel to the longitudinal direction of the assigned main structure.

9. The method as claimed in claim 1, wherein at least one end edge of the at least one optically non-resolvable auxiliary structure is formed by two end terminating edges, which taper to a point in the longitudinal direction of the auxiliary structure.

10. The method as claimed in claim 9, wherein at least one of the end terminating edges runs parallel to the longitudinal direction of the assigned main structure.

11. The method as claimed in claim 1, wherein the optically non-resolvable auxiliary structures are positioned with the aid of a simulation program.

12. The method as claimed in claim 1, wherein the at least one optically non-resolvable auxiliary structure includes at least two optically non-resolvable auxiliary structures that are arranged in a group.

13. The method as claimed in claim 1, wherein two main structures are assigned an optically non-resolvable auxiliary structure, and wherein the width of the auxiliary structure and the distance between the auxiliary structure and the adjacent main structures are chosen in a manner dependent on the distance between the two assigned main structures and/or the structure width of the two main structures.

14. The method as claimed in claim 13, wherein the width of the optically non-resolvable auxiliary structure is adapted to the grid point spacing of the layout structure.

15. The method as claimed in claim 1, wherein a model-based OPC method or a rule-based OPC method is carried out as the OPC method.

16. A photomask for use in fabricating a semiconductor device, the photomask comprising:
a first main structure extending in a first direction;
a second main structure spaced from the first main structure, the second main structure extending in the first direction such that at least a portion of the first main structure extends in parallel to at least a portion of the second main structure; and
at least one optically non-resolvable auxiliary structure disposed between the first main structure and the second main structure, the at least one optically non-resolvable auxiliary structure extending in a second direction that is oblique to the first direction.

17. A method of making a semiconductor device, the method comprising:
providing a photomask that includes a main structure extending in a first direction and at least one optically non-resolvable auxiliary structure adjacent to the main structure, the at least one optically non-resolvable auxiliary structure extending in a second direction that is oblique to the first direction;
providing a semiconductor wafer;
coating a photoresist over an upper surface of the semiconductor wafer;
irradiating the photoresist through the photomask to create a pattern in the photoresist;
removing portions of the photoresist based upon the pattern; and
changing the surface of the wafer based upon the pattern.

18. The method of claim 17, wherein the at least one optically non-resolvable auxiliary structure comprises a plurality of non-resolvable auxiliary structures that extend in the second direction and are uniformly spaced from one another.

19. The method of claim 17, wherein the second direction and the first direction are at an angle of between about 30 and 60 degrees relative to one another.

20. The method of claim 19, wherein at least one end edge of the at least one optically non-resolvable auxiliary structure runs parallel to the first direction.
